(19) United States
(12) Patent Application Publication
(10) Pub. No.: US 2025/0246564 A1
(43) Pub. Date: Jul. 31, 2025

(54) PACKAGE CONDUCTIVE TERMINALS WITH REDUCED PALLADIUM VOLUMES

(71) Applicant: TEXAS INSTRUMENTS INCORPORATED, Dallas, TX (US)

(72) Inventors: Rafael Jose Lizares GUEVARA, Angeles (PH); Mharpee T. GONZALES, Mabalacat City (PH); Dainty Monica ORATE, Malaybalay City (PH)

(21) Appl. No.: 18/428,718

(22) Filed: Jan. 31, 2024

(51) Int. Cl. H01L 23/00; H01L 21/56; H01L 23/31

(52) U.S. Cl. CPC H01L 24/05; H01L 21/56; H01L 23/3107; H01L 24/03; H01L 24/48; H01L 24/85; H01L 2224/0346; H01L 2224/05147; H01L 2224/05155; H01L 2224/05166; H01L 2224/05184; H01L 2224/05664; H01L 2224/85

(57) ABSTRACT

A method for manufacturing a semiconductor package comprises applying a seed layer on a semiconductor wafer; applying and patterning a photoresist on the seed layer; and plating a first copper member in a cavity of the photoresist, a top surface of the first copper member facing away from the wafer. The method comprises removing the photoresist and a portion of the seed layer; applying and patterning an insulative layer on the wafer and on the first copper member, the insulative layer having a cavity, the largest horizontal area of the insulative layer cavity being smaller than a horizontal area of a top surface of the first copper member; and plating a second copper member in the cavity of the insulative layer. The method includes plating a nickel member on the second copper member in the cavity of the insulative layer; plating a palladium member on the nickel member in the cavity of the insulative layer; singulating the wafer to produce a semiconductor die having the first and second copper, nickel, and palladium members; coupling a bond wire to the palladium member; and covering the semiconductor die and the bond wire with a mold compound.

### BACKGROUND

During semiconductor chip manufacturing, circuits may be formed on a semiconductor wafer. The wafer may be separated (or “singulated”) into a plurality of semiconductor dies, where each die has a circuit formed thereon. Each die is then processed to form a semiconductor package that may be integrated with an electronic device (e.g., computers, smartphones). A package may include a surface having copper conductive terminals (e.g., leads) that facilitate connections to other components. The package may also include copper conductive terminals (e.g., bond pads) inside the package to facilitate connections between components within the package.

### SUMMARY

In examples, a method for manufacturing a package comprises applying a seed layer on a semiconductor wafer; applying and patterning a photoresist on the seed layer; and plating a first copper member in a cavity of the photoresist, a top surface of the first copper member facing away from the wafer. The method comprises removing the photoresist and a portion of the seed layer; applying and patterning an insulative layer on the wafer and on the first copper member, the insulative layer having a cavity, the largest horizontal area of the insulative layer cavity being smaller than a horizontal area of a top surface of the first copper member; and plating a second copper member in the cavity of the insulative layer. The method includes plating a nickel member on the second copper member in the cavity of the insulative layer; plating a palladium member on the nickel member in the cavity of the insulative layer; singulating the wafer to produce a semiconductor die having the first and second copper, nickel, and palladium members; coupling a bond wire to the palladium member; and covering the semiconductor die and the bond wire with a mold compound.

In examples, a package comprises a semiconductor die including a circuit and a first copper member coupled to the circuit and having a first maximal horizontal area. The package includes a second copper member coupled to the first copper member, the second copper member having a second maximal horizontal area that is smaller than the first maximal horizontal area. The package includes a nickel member contacting the second copper member and having a third maximal horizontal area that is smaller than the first maximal horizontal area. The package comprises a palladium member contacting the nickel member and having a fourth maximal horizontal area that is smaller than the first maximal horizontal area, the palladium member having a top surface facing away from the semiconductor die. The package includes an insulative layer contacting the semiconductor die and the first copper, second copper, nickel, and palladium members, a top surface of the insulative layer facing away from the semiconductor die and approximately flush with the top surface of the palladium member. The package includes a bond wire coupled to the top surface of the palladium member and a mold compound covering the semiconductor die, the bond wire, the insulative layer, and the first copper, second copper, nickel, and palladium members.

In examples, a package comprises a semiconductor die including a circuit, and a first copper member coupled to the circuit and having a top surface facing away from the semiconductor die, the first copper member having a first maximal horizontal area. The package also comprises titanium-tungsten contacting the top surface of the first copper member; a second copper member contacting the titanium-tungsten; and a nickel member contacting the second copper member. The package includes a palladium member contacting a surface of the nickel member that faces away from the semiconductor die, the palladium member having a second maximal horizontal area that is smaller than the first maximal horizontal area. The package comprises an insulative layer contacting the semiconductor die and the first copper, second copper, nickel, and palladium members, a top surface of the insulative layer facing away from the semiconductor die and positioned within 2 microns of a top surface of the palladium member that faces away from the semiconductor die. The package also includes a bond wire coupled to the top surface of the palladium member. The package comprises a mold compound covering the semiconductor die, the bond wire, the insulative layer, and the first copper, second copper, nickel, and palladium members.

### BRIEF DESCRIPTION OF THE DRAWINGS

FIGS. 1A-14C are a process flow of a method for manufacturing a package having conductive terminals with reduced palladium volumes, in accordance with various examples.

FIG. 15 is a flow diagram of a method for manufacturing a package having conductive terminals with reduced palladium volumes, in accordance with various examples.

### DETAILED DESCRIPTION

Within a semiconductor package, copper conductive terminals may be coated with nickel, as nickel is harder than copper, prevents copper diffusion, and is suitable for the formation of connections, such as by wirebonding. However, nickel is prone to oxidation, and thus nickel may be coated with palladium to operate as an oxidation barrier. Palladium is expensive, and thus it is desirable to reduce the volume of palladium used to coat the nickel member of a conductive terminal. Current manufacturing techniques frequently entail applying more palladium than is necessary on a given conductive terminal, but reducing the volume of palladium applied can be technically challenging.

This disclosure describes various examples of systems and techniques for reducing the volume of palladium applied to copper conductive terminals in packages relative to the volume of palladium that would otherwise be used. In examples, a method for manufacturing a package comprises applying a seed layer on a semiconductor wafer; applying and patterning a photoresist on the seed layer; plating a first copper member in an orifice of the photoresist, a top surface of the first copper member facing away from the wafer; and removing the photoresist and a portion of the seed layer. The method also comprises applying and patterning an insulative layer on the wafer and on the first copper member, the insulative layer having an orifice, the largest horizontal area of the insulative layer orifice being smaller than a horizontal area of a top surface of the first copper member. The method also comprises plating a second copper member in the orifice of the insulative layer; plating a nickel member on the second copper member in the orifice of the insulative layer; plating a palladium member on the nickel member in the orifice of the insulative layer; singulating the wafer to produce a semiconductor die having the first and second copper, nickel, and palladium members; coupling a bond wire to the palladium member; and covering the semiconductor die and the bond wire with a mold compound.

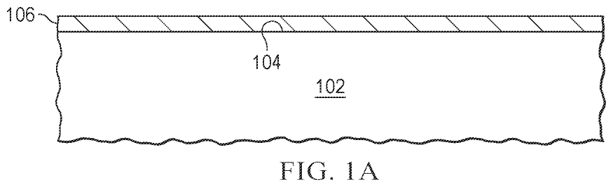

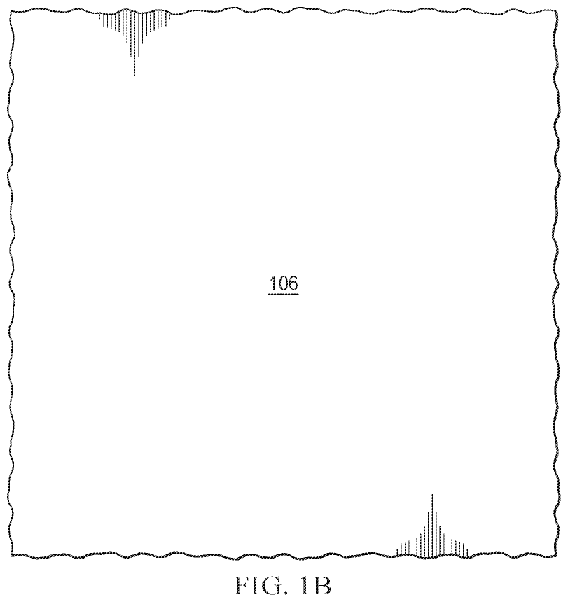

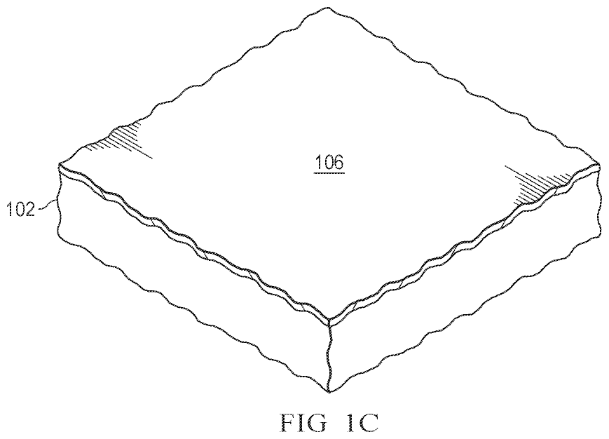

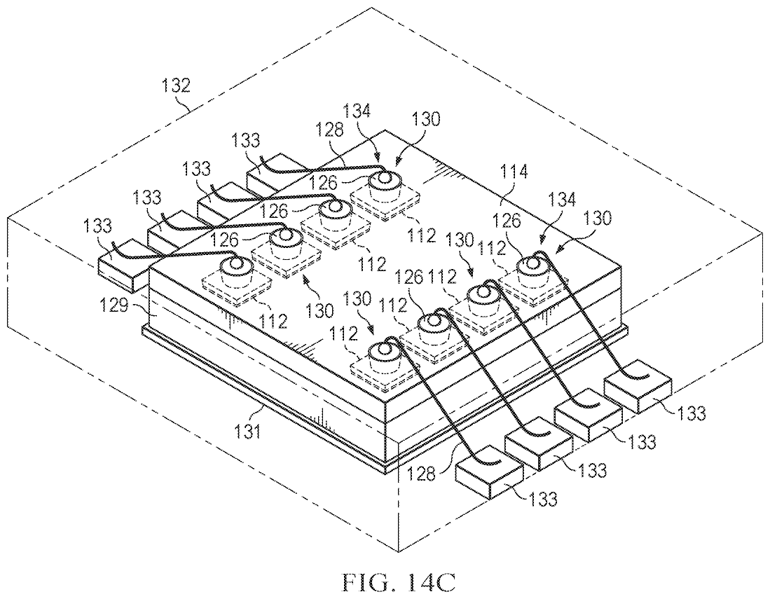

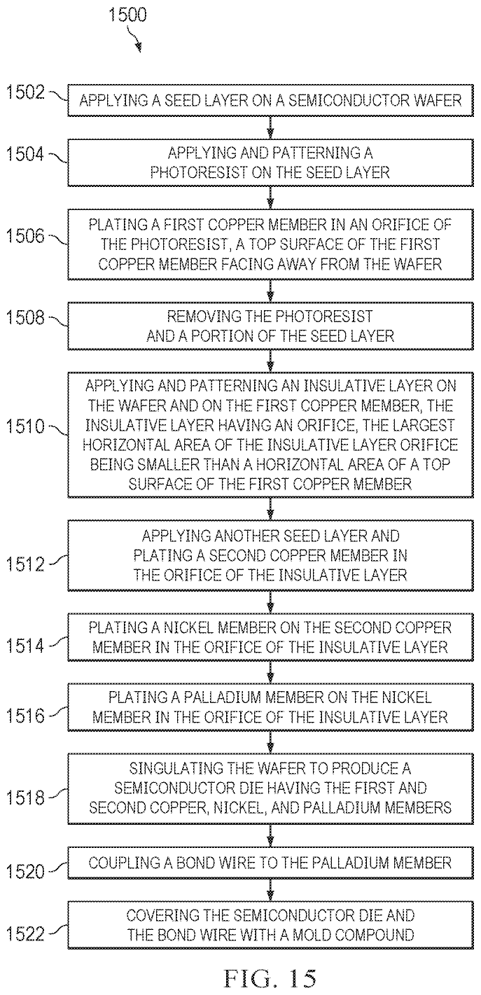

FIGS. 1A-14C are a process flow of a method for manufacturing a package having conductive terminals with reduced palladium volumes, in accordance with various examples. FIG. 15 is a flow diagram of a method for manufacturing a package having conductive terminals with reduced palladium volumes, in accordance with various examples. Accordingly, the process flow of FIGS. 1A-14C is now described in parallel with the flow diagram of FIG. 15. At least some of the various actions shown in FIGS. 1A-15 may be performed at the wafer stage (i.e., before the wafer is diced), meaning that the specific actions shown are illustrative and, in practice, are performed on multiple areas of the semiconductor wafer 102.

The method 1500 includes applying a seed layer on a semiconductor wafer (1502). FIG. 1A is a profile view of a portion of a semiconductor wafer 102, such as a silicon wafer or a gallium nitride wafer. The semiconductor wafer 102 includes a device side 104 in and/or on which circuitry may be formed. A seed layer 106 may be sputtered on the device side 104. The seed layer 106 may comprise copper, titanium-tungsten, a combination thereof, or any other suitable metal or metal alloy. FIG. 1B is a top-down view of the structure of FIG. 1A, in accordance with various examples. FIG. 1C is a perspective view of the structure of FIG. 1A, in accordance with various examples.

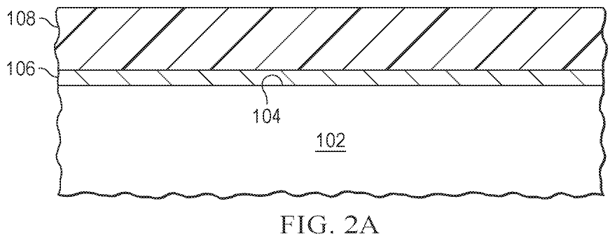

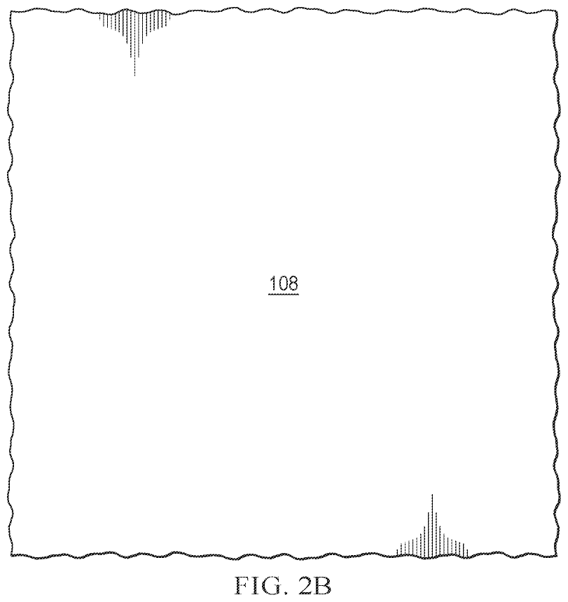

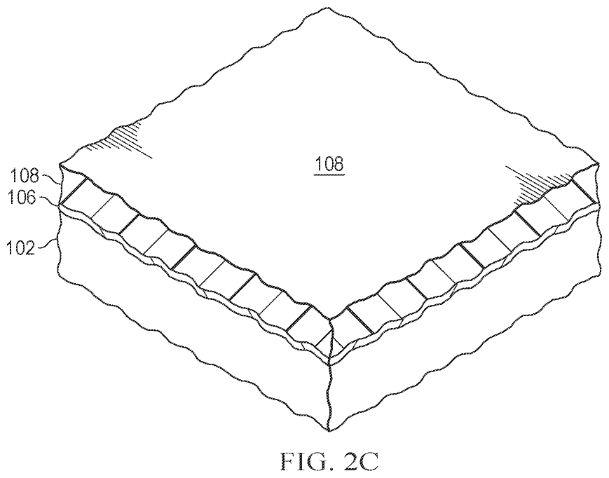

The method 1500 includes applying and patterning a photoresist on the seed layer (1504). In examples, applying and patterning a photoresist may include depositing a photoresist, exposing one or more areas of the photoresist (e.g., using an appropriate mask), and developing the photoresist using an appropriate developing solution to either remove the areas that were exposed or the areas that were not exposed (e.g., depending on the type of photoresist and mask), resulting in a patterned photoresist. FIG. 2A is an illustrative, profile view of the structure of FIG. 1A, except that a photoresist layer 108 is deposited on top of the seed layer 106. The thickness of the photoresist layer 108 must be selected based on the desired height of the bond pad that is being formed by the process of FIGS. 1A-14C. A thicker photoresist layer 108 will produce a thicker bond pad, while a thinner photoresist layer 108 will produce a thinner bond pad. FIG. 2B is a top-down view of the structure of FIG. 2A, in accordance with various examples. FIG. 2C is a perspective view of the structure of FIG. 2A, in accordance with various examples.

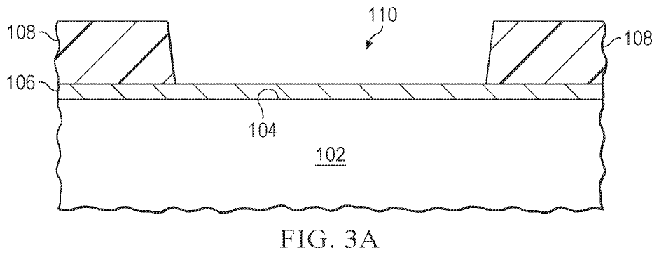

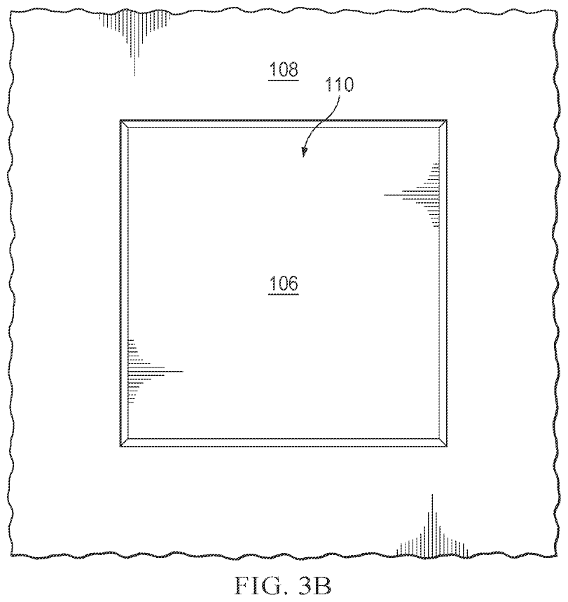

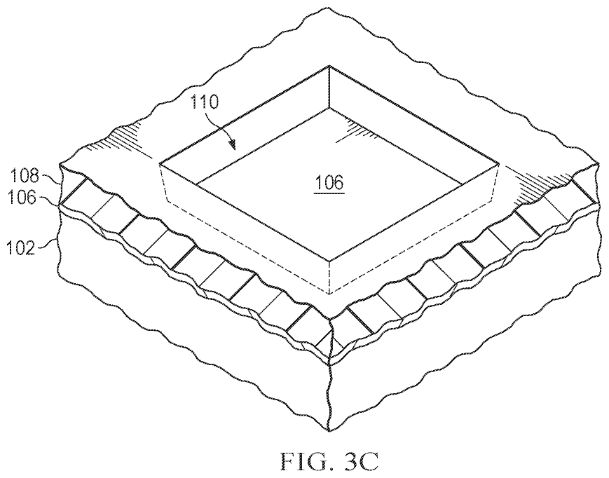

The method 1500 includes plating a first copper member in an orifice, also referred to as a cavity, of the photoresist, with a top surface of the first copper member facing away from the wafer (1506). FIG. 3A is an illustrative, profile view of the structure of FIG. 2A, except that a cavity 110 has been formed in the photoresist layer 108. The cavity 110 may be formed by a photolithography process, using the appropriate masks, light, developing agent, etc. The cavity 110 must extend through the entire thickness of the photoresist layer 108 such that the seed layer 106 is exposed to the cavity 110. This is because a metal layer will be plated within the cavity 110, and for the metal layer to be plated within the cavity 110, the seed layer 106 must be exposed to the cavity 110. FIG. 3B is a top-down view of the structure of FIG. 3A, in accordance with various examples. FIG. 3C is a perspective view of the structure of FIG. 3A, in accordance with various examples.

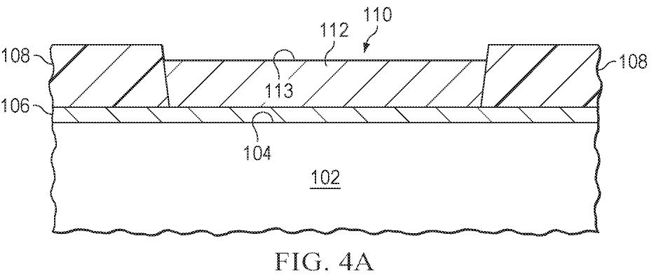

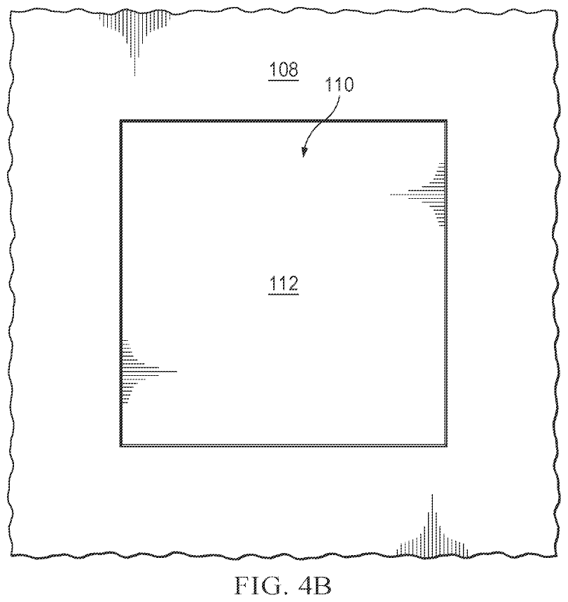

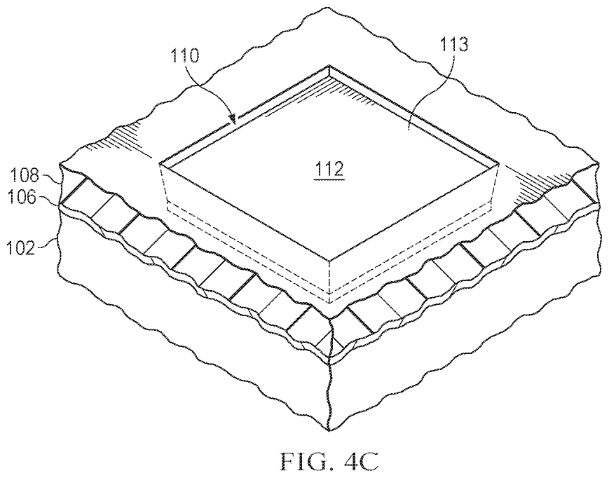

FIG. 4A is an illustrative, profile view of the structure of FIG. 3A, except that a copper member 112 is plated within cavity 110. The thickness of the copper member 112 must be plated according to the desired thickness of the bond pad that will ultimately be formed using the copper member 112. The copper member 112 has a top surface 113 that faces away from the semiconductor wafer 102. The copper member 112 is in vertical alignment with circuitry formed in the semiconductor wafer 102. FIG. 4B is a top-down view of the structure of FIG. 4A, in accordance with various examples. FIG. 4C is a perspective view of the structure of FIG. 4A, in accordance with various examples.

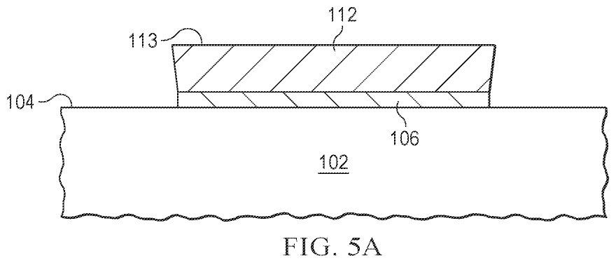

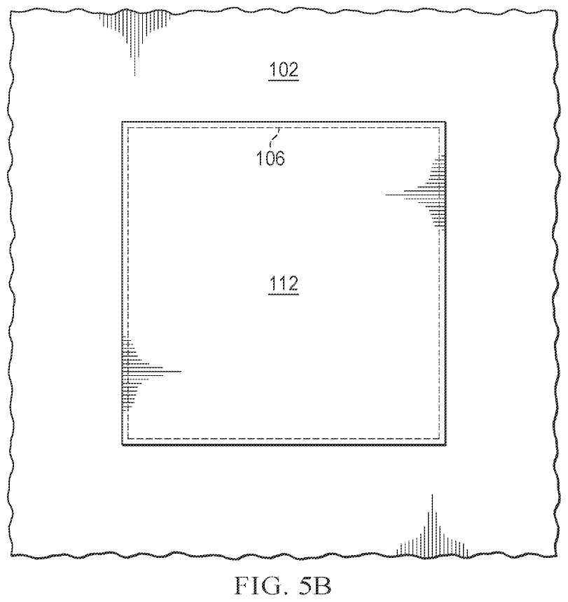

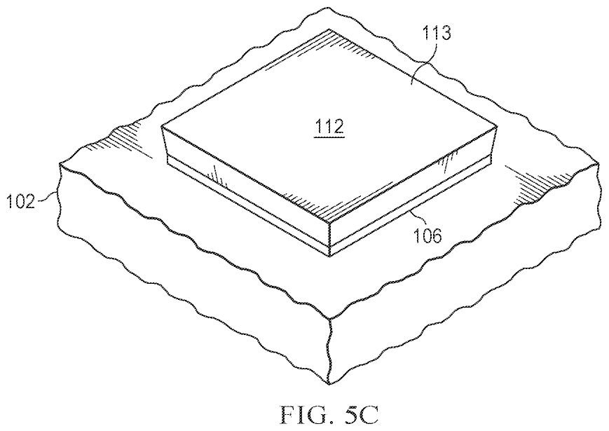

The method 1500 includes removing the photoresist and a portion of the seed layer (1508). FIG. 5A is an illustrative, profile view of the structure of FIG. 4A, except that the photoresist layer 108, as well as the portions of the seed layer 106 that were not directly underneath the copper member 112, have been removed (e.g., by stripping and etching, such as by using chemical, thermal, or plasma stripping, and such as by wet chemical etching or dry etching (e.g., plasma etching)). The portion of the seed layer 106 directly underneath (i.e., in vertical alignment with) the copper member 112 remains in place. FIG. 5B is a top-down view of the structure of FIG. 5A, in accordance with various examples. FIG. 5C is a perspective view of the structure of FIG. 5A, in accordance with various examples.

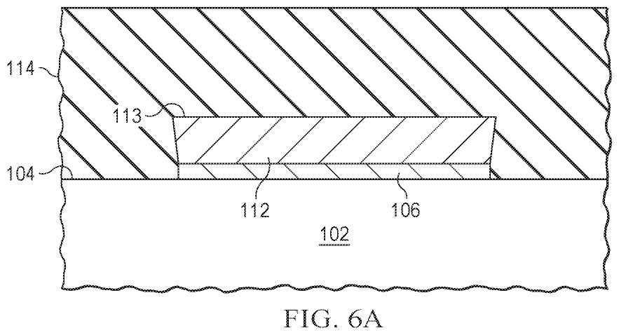

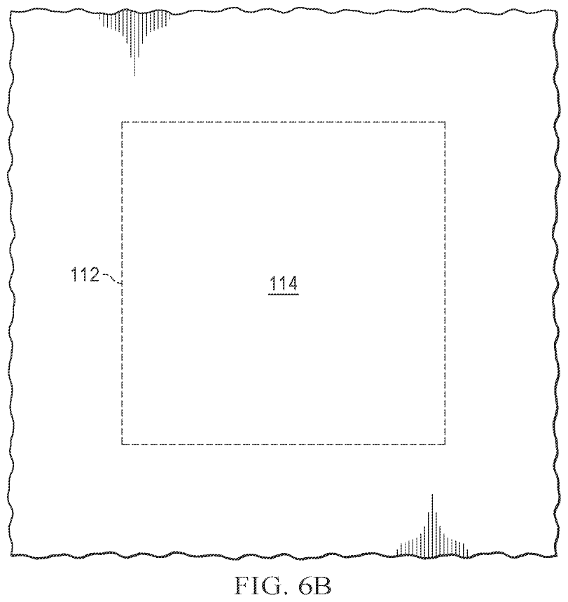

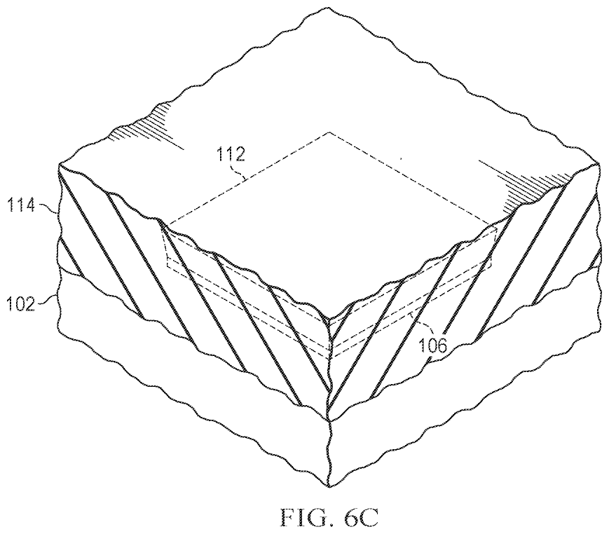

The method 1500 includes applying and patterning an insulative layer on the wafer and on the first copper member (1510). The insulative layer has an orifice, also referred to herein as a cavity (1510). The largest horizontal (i.e., approximately parallel to the device side 104 of the semiconductor wafer 102) area of the insulative layer orifice is smaller than a horizontal area of a top surface of the first copper member (1510). FIG. 6A is an illustrative, profile view of the structure of FIG. 5A, except that an insulative layer 114, such as polyimide (PI), is deposited on the device side 104 and the surface 113. The thickness of the insulative layer 114, in tandem with the thickness of the copper member 112, determines the thickness of the bond pad that is being formed by the process flow of FIGS. 1A-14C. The thickness of the insulative layer 114 should be chosen accordingly. FIG. 6B is a top-down view of the structure of FIG. 6A, in accordance with various examples. FIG. 6C is a perspective view of the structure of FIG. 6A, in accordance with various examples.

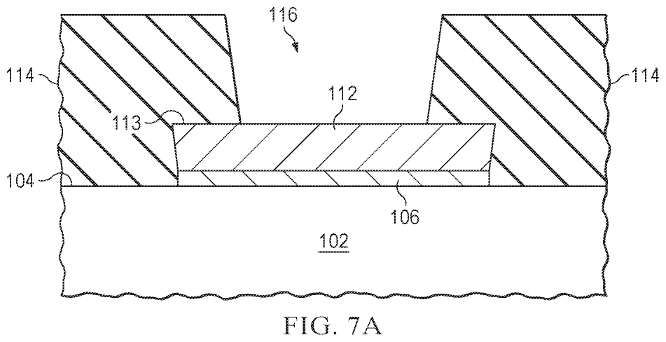

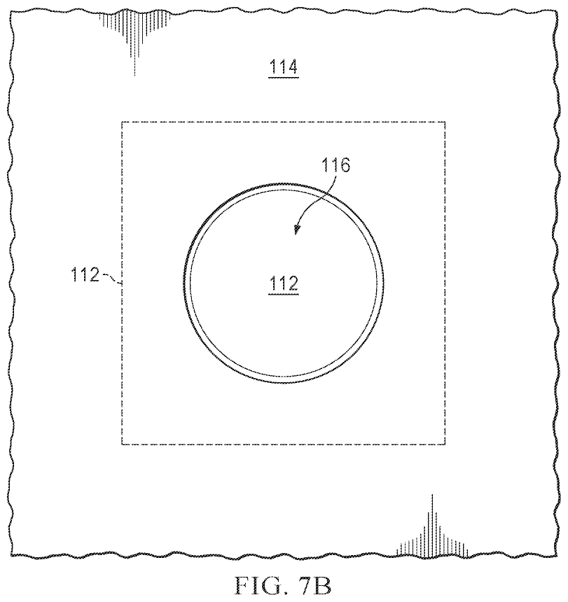

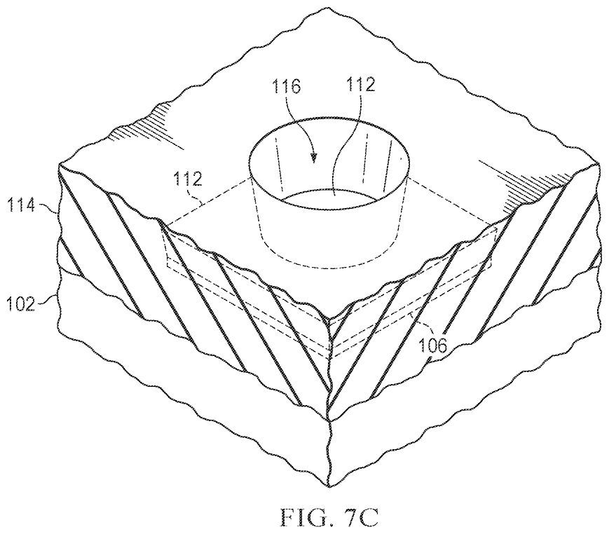

FIG. 7A is an illustrative, profile view of the structure of FIG. 6A, except that a cavity or orifice 116 is formed in the insulative layer 114, as shown. The cavity 116 is formed by a photolithographic process, using the appropriate masks, light, developing agent, etc. The cavity 116 has a varying horizontal dimension that is narrowest (i.e., has the smallest horizontal area) closest to the copper member 112 and is widest (i.e., has the greatest horizontal area) farthest from the copper member 112. In addition, the largest horizontal area of the cavity 116 is smaller than a horizontal area of the surface 113. FIG. 7B is a top-down view of the structure of FIG. 7A, in accordance with various examples. FIG. 7C is a perspective view of the structure of FIG. 7A, in accordance with various examples.

Photoresist layer 108 and the insulative layer 114 are formed of different polymer types. For example, insulative layer 114 may be a polyimide and photoresist layer 108 is, as the name indicates, a photoresist. The exposure energy applied to each of the photoresist layer 108 and the insulative layer 114 during photolithography differs because of the fact that different materials are used in the photoresist layer 108 versus the insulative layer 114. As a result of the differing exposure energies, the slope of the cavity 116 wall (77-80 degrees with respect to the horizontal plane in which the bottom surface of the cavity 116 lies) is greater than the slope of the cavity 110 wall (82-88 degrees with respect to the horizontal plane in which the bottom surface of the cavity 110 lies).

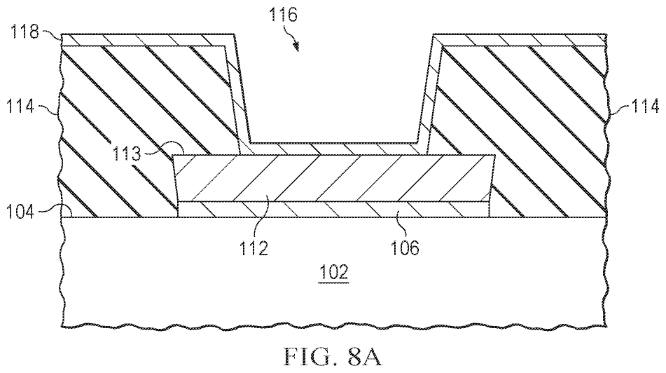

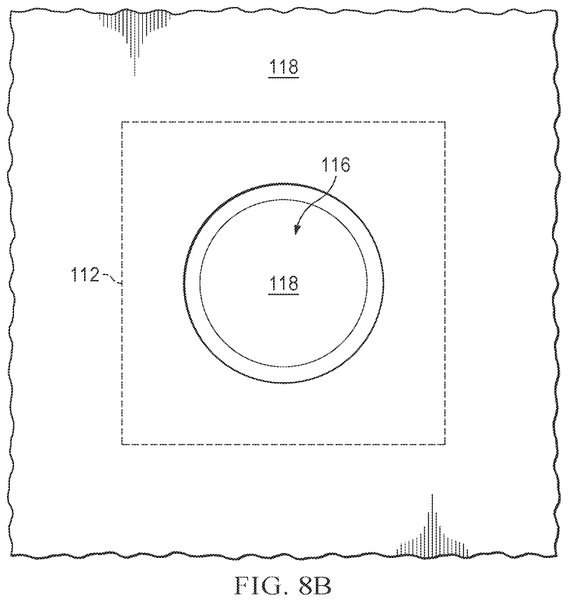

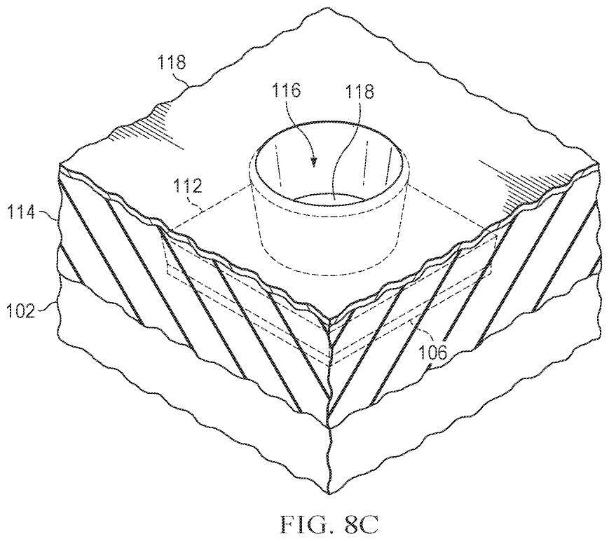

The method 1500 includes sputtering another seed layer and plating a second copper member in the orifice of the insulative layer (1512). FIG. 8A is an illustrative, profile view of the structure of FIG. 7A, except that a seed layer 118 is deposited on the insulative layer 114 and on the surface 113. The seed layer 118 is deposited by a sputtering process and includes copper, titanium-tungsten, a combination thereof, or another suitable metal or metal alloy. FIG. 8B is a top-down view of the structure of FIG. 8A, in accordance with various examples. FIG. 8C is a perspective view of the structure of FIG. 8A, in accordance with various examples.

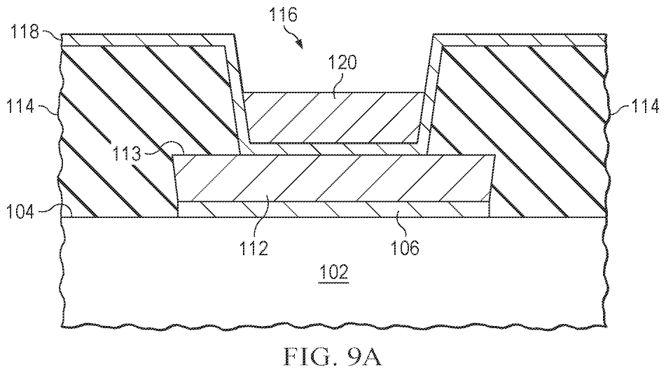

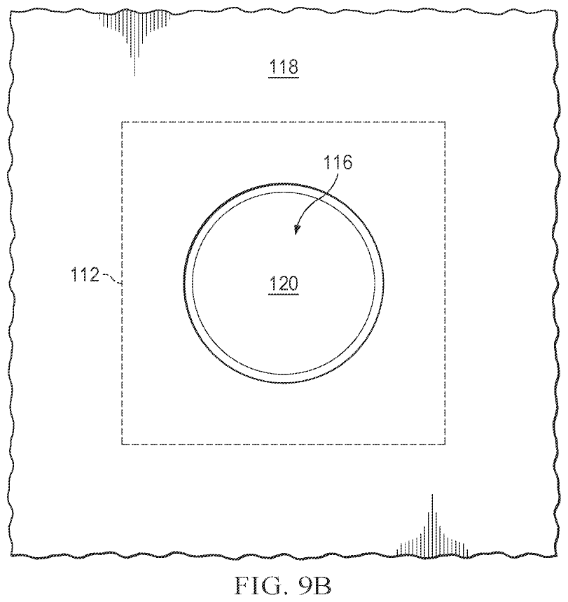

FIG. 9A is an illustrative, profile view of the structure of FIG. 8A, except that a copper member 120 has been plated in the cavity 116 using the seed layer 118. The thickness of the copper member 120 partially determines the thickness of the bond pad that is being formed by the process of FIGS. 1A-14C. Thus, the copper member 120 should be formed accordingly. Because the copper member 120 is formed in the cavity 116, the widest part (including the maximal horizontal area) of the copper member 120 is smaller than the horizontal area (i.e., maximal horizontal area) of the copper member 112, as shown. FIG. 9B is a top-down view of the structure of FIG. 9A, in accordance with various examples. FIG. 9C is a perspective view of the structure of FIG. 9A, in accordance with various examples.

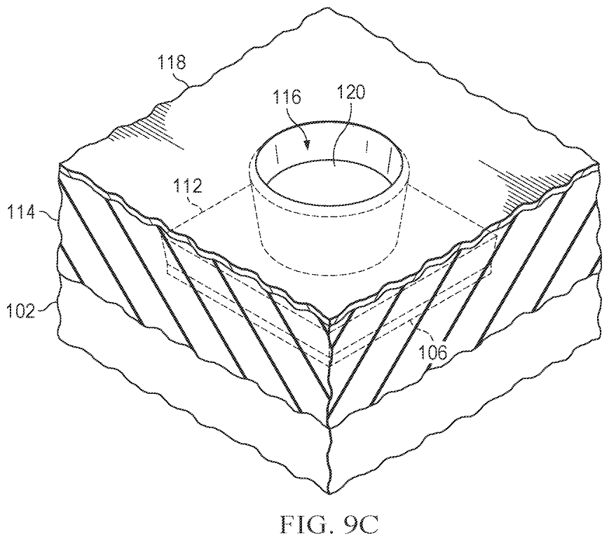

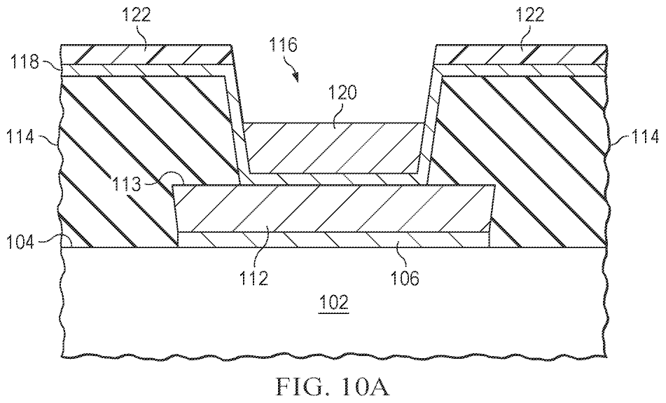

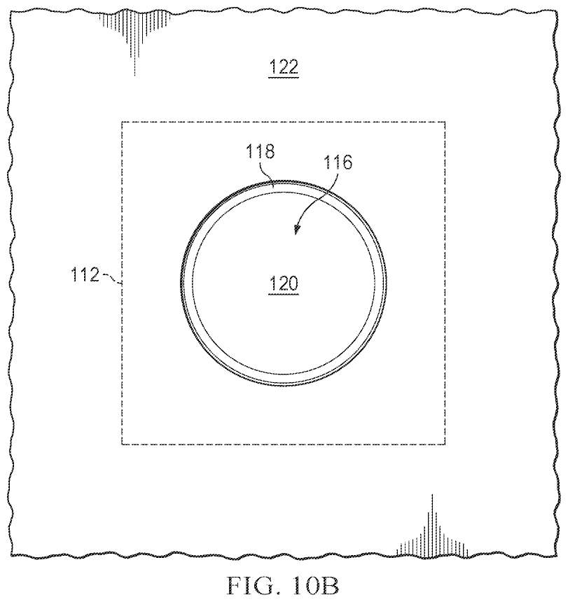

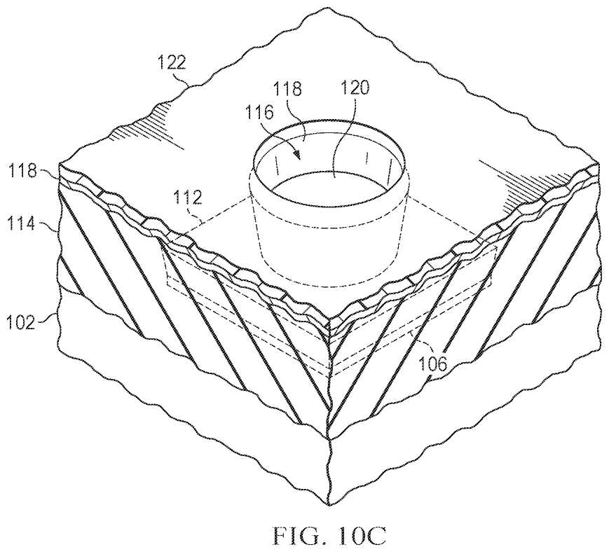

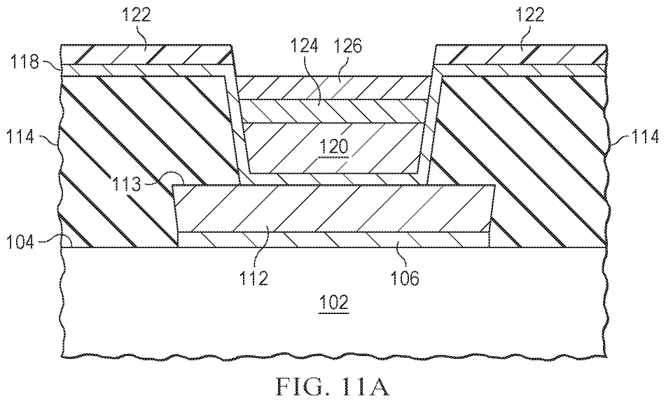

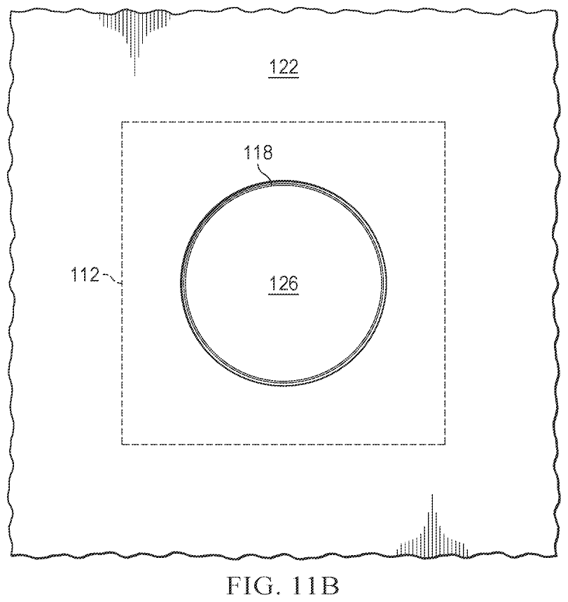

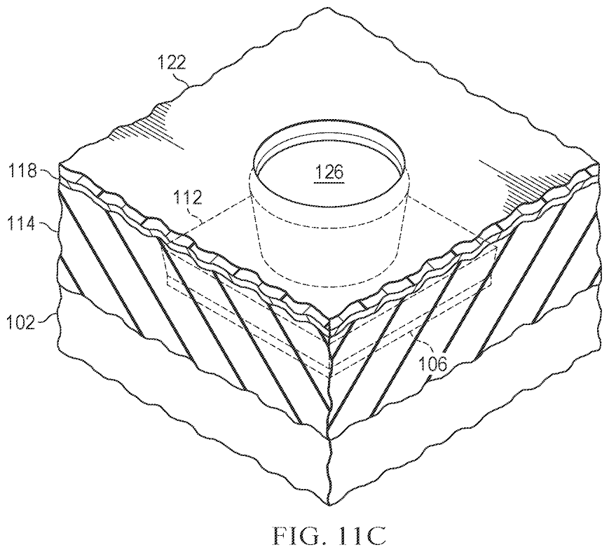

The method 1500 includes plating a nickel member on the second copper member in the orifice of the insulative layer (1514) and plating a palladium member on the nickel member in the orifice of the insulative layer (1516). FIGS. 10A-11C show the application of the nickel and palladium members as described in 1514 and 1516. In particular, FIG. 10A shows the application of a thin layer of photoresist 122 on the seed layer 118. The photoresist 122 may also be deposited on the portions of metal exposed to the cavity 116, such as on the top surface of the copper member 120 and on the portions of the seed layer 118 lining the cavity 116, but these portions of the photoresist 122 may be removed by a photolithographic process, for example. The photoresist 122 prevents metals, such as nickel and palladium, from being plated on the portions of the seed layer 118 where the photoresist 122 is present. The photoresist 122 has a thickness ranging from 1 micron to 2 microns, with a thickness greater than this range being disadvantageous because it adds manufacturing time and costs, and with a thickness less than this range being disadvantageous because it is not adequate to reliably prevent plating in the areas where the photoresist 122 is present. FIG. 10B is a top-down view of the structure of FIG. 10A, in accordance with various examples. FIG. 10C is a perspective view of the structure of FIG. 10A, in accordance with various examples.

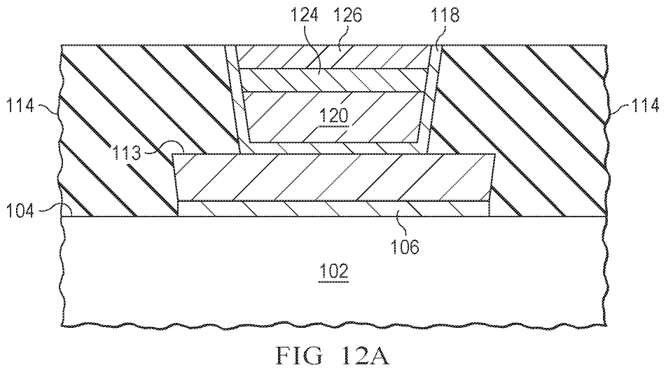

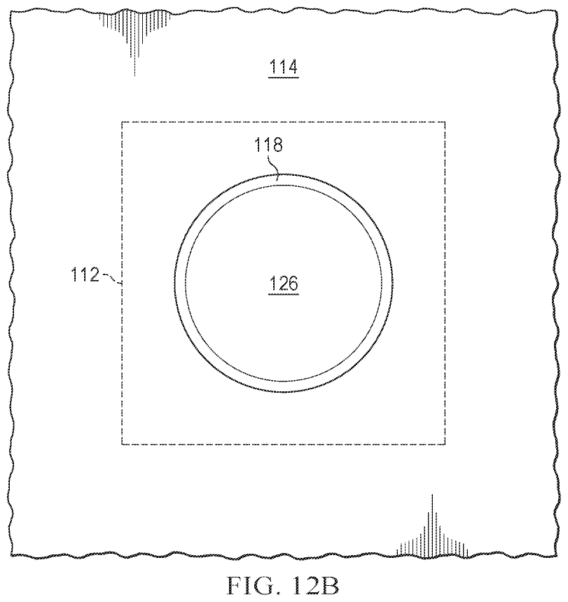

FIG. 11A shows the plating of a nickel member 124 on the top surface of the copper member 120 (i.e., the surface of the copper member 120 facing away from the semiconductor wafer 102), as well as the plating of a palladium member 126 on the top surface of the nickel member 124 (i.e., the surface of the nickel member 124 facing away from the semiconductor wafer 102). (The nickel member 124 is a nickel layer, and various other structures described herein as “members” also may be considered “layers,” such as the copper member 120 and the palladium member 126, for example.) The nickel member 124 has a maximal horizontal area that is less than that of the copper member 112, and that is greater than that of the copper member 120. The palladium member 126 has a maximal horizontal area that is less than that of the copper member 112, and that is greater than that of the nickel member 124. The copper member 120 has a maximal horizontal area less than that of the copper member 112, the nickel member 124, and the palladium member 126. The nickel member 124 has a thickness ranging from 1 micron to 3 microns, with a thickness greater than this range being disadvantageous because of unacceptably increased manufacturing costs, and with a thickness less than this range being disadvantageous because of detrimental effects on copper diffusion. More specifically, nickel may serve as a diffusion barrier between copper layers and palladium layers. Nickel has a higher diffusion barrier property compared to copper, meaning that nickel is less prone to diffusion into adjacent materials. By preventing copper diffusion, the nickel layer helps maintain the integrity of the device structure and prevents unwanted interactions between copper and other materials, such as palladium. The minimum horizontal area of the palladium member 126 is at least 1200 microns², with a smaller horizontal area presenting unacceptable technical challenges with respect to plating efficiency. As described herein, the maximal horizontal area of the palladium member 126 is less than that of the copper member 112. FIG. 11B is a top-down view of the structure of FIG. 11A, in accordance with various examples. FIG. 11C is a perspective view of the structure of FIG. 11A, in accordance with various examples. FIG. 12A shows the removal of the photoresist 122 (e.g., by stripping) and the removal of the portion of the seed layer 118 that does not contact the copper member 120, the nickel member 124, or the palladium member 126 (e.g., by etching). FIG. 12B is a top-down view of the structure of FIG. 12A, in accordance with various examples. FIG. 12C is a perspective view of the structure of FIG. 12A, in accordance with various examples.

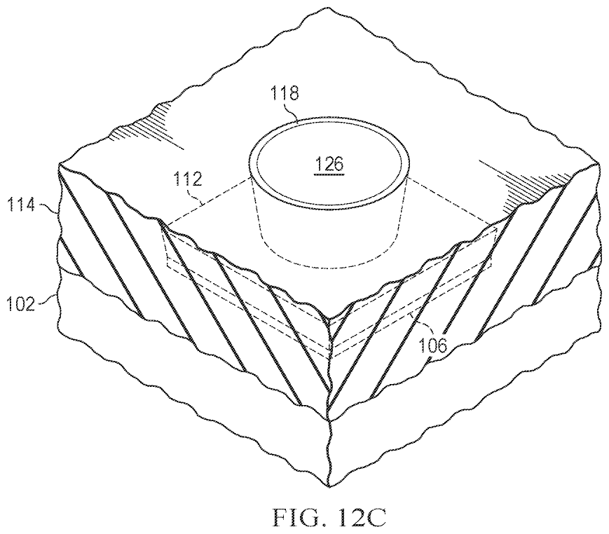

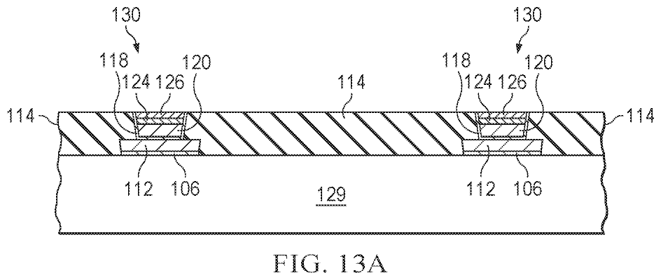

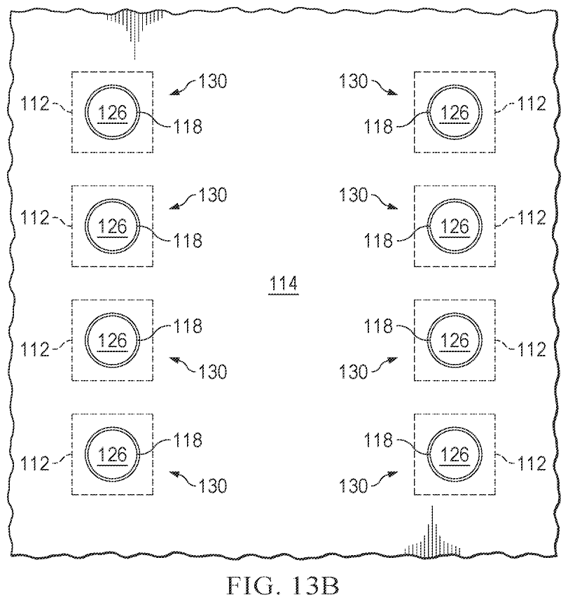

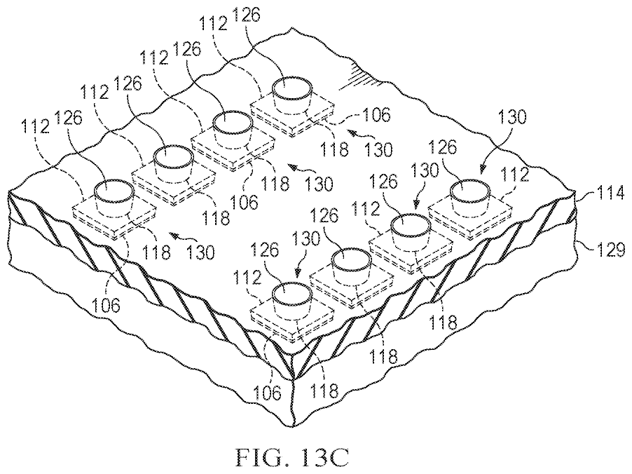

The method 1500 includes singulating the semiconductor wafer to produce a semiconductor die having the first and second copper, nickel, and palladium members (1518). FIG. 13A is an illustrative profile view of the structure of FIG. 12A, but the view is expanded to depict a semiconductor die 129 that has been singulated from the semiconductor wafer 102 and that includes multiple bond pads 130, as opposed to a single bond pad shown in FIG. 12A. The copper member 112 is in vertical alignment with circuitry formed in the semiconductor die 129. FIG. 13B is a top-down view of the structure of FIG. 13A, in accordance with various examples. FIG. 13C is a perspective view of the structure of FIG. 13A, in accordance with various examples.

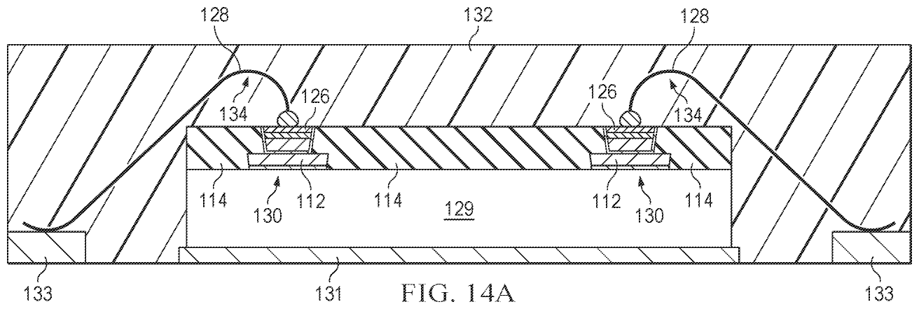

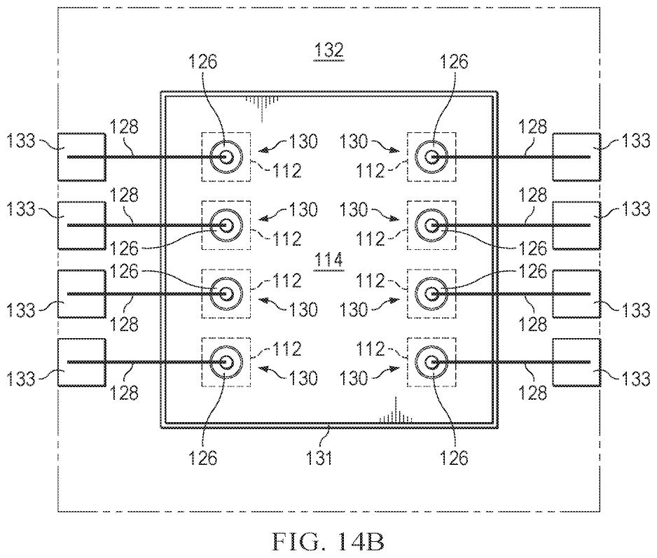

The method 1500 includes coupling a bond wire to the palladium member (1520) and covering the semiconductor die and the bond wire with a mold compound (1522). Coupling a bond wire to the palladium member may be accomplished in any suitable manner. In some examples, a ball bond may be formed on the palladium member, and the bond wire extending from the ball bond may be stitch bonded to a suitable conductive terminal. Further, a mold compound may be applied in any suitable manner. In some examples, a structure to be covered by a mold compound may be positioned within a suitable mold chase and the mold chase may be closed to partially or fully encapsulate the structure, after which the mold compound may be injected or otherwise applied and permitted to flow on and around the structure to cover the structure. FIG. 14A is an illustrative profile view of the structure of FIG. 13A, except that the semiconductor die 129 is coupled to a die pad 131, bond wires 128 are coupled to the bond pads 130 and to conductive terminals 133, and a mold compound 132 covers the semiconductor die 129, the die pad 131, the insulative layer 114, the bond pads 130, the bond wires 128, and the conductive terminals 133, as shown, to form a completed package. FIG. 14B is a top-down view of the structure of FIG. 14A, in accordance with various examples. FIG. 14C is a perspective view of the structure of FIG. 14A, in accordance with various examples.

In the completed package shown in FIGS. 14A-14C, the bond pads 130 contain less palladium than would be present in bond pads manufactured using other techniques. Because of the manufacturing techniques described above, the palladium member 126 has a maximal horizontal area that is less than the horizontal area of the top surface of the copper member 112 (i.e., the surface of the copper member 112 facing away from the semiconductor die 129). In addition, the palladium member 126 has a total volume that is less than would otherwise be the case had the manufacturing techniques described herein not been used. This results in significant reductions in manufacturing costs. In addition, the top surfaces of the bond pads 130 (i.e., the top surfaces of the palladium layers of the bond pads 130) are approximately flush with the top surface of the insulative layer 114 (i.e., within 2 microns to permit sufficient clearance from the top of the insulative layer 114 to avoid overplating), meaning that bond wires 128 coupled to the bond pads 130 may have loop 134 angles that are less sharp (i.e., more obtuse) than would otherwise be required if the top surfaces of the bond pads 130 were not approximately flush with the top surface of the insulative layer 114.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A method for manufacturing a semiconductor package, comprising:
applying a seed layer on a semiconductor wafer;
applying and patterning a photoresist on the seed layer;
plating a first copper member in a cavity of the photoresist, a top surface of the first copper member facing away from the wafer;
removing the photoresist and a portion of the seed layer;
applying and patterning an insulative layer on the wafer and on the first copper member, the insulative layer having a cavity, the largest horizontal area of the insulative layer cavity being smaller than a horizontal area of a top surface of the first copper member;
plating a second copper member in the cavity of the insulative layer;
plating a nickel member on the second copper member in the cavity of the insulative layer;
plating a palladium member on the nickel member in the cavity of the insulative layer;
singulating the wafer to produce a semiconductor die having the first and second copper, nickel, and palladium members;
coupling a bond wire to the palladium member; and
covering the semiconductor die and the bond wire with a mold compound.

2. The method of claim 1, wherein the insulative layer is polyimide.

3. The method of claim 1, wherein the palladium member has a largest horizontal area that is smaller than the horizontal area of the top surface of the first copper member.

4. The method of claim 1, wherein the first copper member is in vertical alignment with a circuit in the semiconductor die.

5. The method of claim 1, further comprising applying a second seed layer on a top surface of the insulative layer, on a surface of the cavity of the insulative layer, and on the top surface of the first copper member.

6. The method of claim 5, wherein applying the second seed layer comprises sputtering a combination of copper and titanium-tungsten.

7. The method of claim 5, further comprising applying a layer of photoresist on portions of the second seed layer that are not in the cavity of the insulative layer.

8. The method of claim 7, wherein the application of the layer of photoresist on the portions of the second seed layer that are not in the cavity of the insulative layer occurs prior to plating the nickel and palladium members.

9. A semiconductor package, comprising:
a semiconductor die including a circuit;
a first copper member coupled to the circuit and having a first maximal horizontal area;
a second copper member coupled to the first copper member, the second copper member having a second maximal horizontal area that is smaller than the first maximal horizontal area;
a nickel member contacting the second copper member and having a third maximal horizontal area that is smaller than the first maximal horizontal area;
a palladium member contacting the nickel member and having a fourth maximal horizontal area that is smaller than the first maximal horizontal area, the palladium member having a top surface facing away from the semiconductor die;
an insulative layer contacting the semiconductor die and the first copper, second copper, nickel, and palladium members, a top surface of the insulative layer facing away from the semiconductor die and approximately flush with the top surface of the palladium member;
a bond wire coupled to the top surface of the palladium member; and
a mold compound covering the semiconductor die, the bond wire, the insulative layer, and the first copper, second copper, nickel, and palladium members.

10. The semiconductor package of claim 9, wherein the insulative layer comprises polyimide.

11. The semiconductor package of claim 9, wherein the top surface of the palladium member is within 2 microns of the top surface of the insulative layer.

12. The semiconductor package of claim 9, wherein the fourth maximal horizontal area is greater than the third maximal horizontal area.

13. The semiconductor package of claim 12, wherein the third maximal horizontal area is greater than the second maximal horizontal area.

14. The semiconductor package of claim 9, wherein the nickel member has a thickness of at least 1 micron.

15. The semiconductor package of claim 9, wherein a minimum horizontal area of the palladium member is at least 1200 microns².

16. The semiconductor package of claim 9, further comprising titanium-tungsten between the first and second copper members.

17. A semiconductor package, comprising:
a semiconductor die including a circuit;
a first copper member coupled to the circuit and having a top surface facing away from the semiconductor die, the first copper member having a first maximal horizontal area;
titanium-tungsten contacting the top surface of the first copper member;
a second copper member contacting the titanium-tungsten;
a nickel member contacting the second copper member;
a palladium member contacting a surface of the nickel member that faces away from the semiconductor die, the palladium member having a second maximal horizontal area that is smaller than the first maximal horizontal area;
an insulative layer contacting the semiconductor die and the first copper, second copper, nickel, and palladium members, a top surface of the insulative layer facing away from the semiconductor die and positioned within 2 microns of a top surface of the palladium member that faces away from the semiconductor die;
a bond wire coupled to the top surface of the palladium member; and
a mold compound covering the semiconductor die, the bond wire, the insulative layer, and the first copper, second copper, nickel, and palladium members.

18. The semiconductor package of claim 17, wherein the second copper member has a maximal horizontal area less than that of the first copper member, the nickel member, and the palladium member.

19. The semiconductor package of claim 17, wherein the palladium member has a minimum horizontal area of at least 1200 microns².

20. The semiconductor package of claim 17, wherein the insulative layer comprises polyimide.
